(19) United States
(12) Patent Application Publication
(10) Pub. No.: US 2025/0017015 A1
(43) Pub. Date: Jan. 9, 2025

(54) SEMICONDUCTOR DEVICE AND SEMICONDUCTOR DEVICE MANUFACTURING METHOD

(71) Applicant: HPSP Co., Ltd., Hwaseong-si (KR)

(72) Inventor: Sungkil CHO, Hwaseong-si (KR)

(73) Assignee: HPSP Co., Ltd., Hwaseong-si (KR)

(21) Appl. No.: 18/892,852

(22) Filed: Sep. 23, 2024

Related U.S. Application Data
(63) Continuation of application No. PCT/KR2023/003745, filed on Mar. 21, 2023.

(30) Foreign Application Priority Data
Mar. 22, 2022 (KR) 10-2022-0035201

(51) Int. Cl. H10B 43/30; H10B 43/27

(52) U.S. Cl. CPC H10B 43/30; H10B 43/27

(57) ABSTRACT

The present invention relates to a semiconductor device and a semiconductor device manufacturing method. The semiconductor device manufacturing method according to one embodiment comprises the steps of: forming a thin film structure on a substrate; forming a trench in the thin film structure; forming a blocking layer for covering at least a part of the trench; forming a charge storage layer on the blocking layer; doping the charge storage layer with carbon; forming a tunneling layer on the charge storage layer; and forming a channel layer for covering the tunneling layer and the substrate. According to embodiments, conformality of the charge storage layer can be increased during the manufacture of the semiconductor device.

### FIELD

The present disclosure relates to a semiconductor device and a method for manufacturing the semiconductor device.

### DESCRIPTION OF RELATED ART

A semiconductor device is a component which is mainly used in electronic circuits or similar devices using an electrical conduction characteristic of a semiconductor. The semiconductors may be classified into a memory semiconductor and a non-memory semiconductor. The memory semiconductor may be classified into a volatile memory such as DRAM or SRAM and a non-volatile memory such as Mask ROM, EP ROM, EEP ROM, and flash memory.

FIG. 1 illustrates a structure of a semiconductor device.

Referring to FIG. 1, in order to manufacture a semiconductor device 1, first, insulating layers 110a to 110e and gate layers 112a to 112e may be alternately and repeatedly deposited on a substrate 100 to form a thin film structure TS.

Next, a trench TR may be formed to extend through the thin film structure TS to expose the substrate 100.

When the trench TR is formed, semiconductor patterns 120, 130, 140, and 150 may be formed in the trench TR. More specifically, a blocking layer 120 covering at least a portion of the trench TR and a charge storage layer 130 disposed on the blocking layer 120 may be formed in the trench TR. In addition, a tunneling layer 140 may be formed on the charge storage layer 130. After the tunneling layer 140 is formed, the channel layer 150 may be formed to cover an exposed portion of the substrate 100.

One of factors determining electrical characteristics of the semiconductor device 1 as shown in FIG. 1 is conformality of the charge storage layer 130. The conformality of the charge storage layer 130 refers to uniformity of a thickness of the charge storage layer 130 measured in a Z-axis direction in FIG. 1. For example, the conformality of the charge storage layer 130 may be defined as a ratio (D2/D1) of a thickness D2 of the charge storage layer 130 measured in a lower region (e.g., a region around the gate layer 112a) of the charge storage layer 130 measured in an upper region (e.g., a region around the gate layer 112e) of the semiconductor device 1. The D2/D1 being closer to 1 means that the conformality is high. The higher the conformality, the more uniform the thickness of the charge storage layer 130.

However, as the number of the insulating layers 110a to 110e and the gate layers 112a to 112e included in the semiconductor device 1 having the structure shown in FIG. 1 is increased, an aspect ratio of the semiconductor device 1 increases. Since a length of the charge storage layer 130 in the Z-axis direction increases as the aspect ratio of the semiconductor device 1 increases, the conformality of the charge storage layer 130 is reduced during the manufacturing process of the semiconductor device 1.

When the conformality of the charge storage layer 130 is reduced, the electrical characteristics of the semiconductor device 1 may be deteriorated. For example, when the conformality of the charge storage layer 130 is reduced, a threshold voltage distribution of cells included in the semiconductor device 1 may increase. In addition, when the conformality of the charge storage layer 130 is reduced, a difference between threshold voltages of the cells included in the semiconductor device 1 or a difference between the threshold voltage of the cells in the upper region of the semiconductor device 1 and the threshold voltage of the cells in the lower region thereof increases.

### DISCLOSURE

### Technical Purpose

A purpose of the present disclosure is to improve electrical characteristics of the semiconductor device by increasing the conformality of the charge storage layer in a process of manufacturing a semiconductor device.

The purpose of the present disclosure is not limited to the above-mentioned purpose, and other purposes and advantages of the present disclosure, which are not mentioned, will be more clearly understood based on embodiments of the present disclosure as described below. In addition, the purposes and advantages of the present disclosure may be realized based on components and combinations thereof described in the Claims.

### Technical Solution

A method for manufacturing a semiconductor device includes forming a thin film structure on a substrate, forming a trench into the thin film structure, forming a blocking layer covering at least a portion of the trench, forming a charge storage layer on the blocking layer, doping carbon into the charge storage layer, forming a tunneling layer on the charge storage layer, and forming a channel layer covering the tunneling layer and the substrate.

A semiconductor device according to an embodiment may include a substrate, a thin film structure formed on the substrate, a blocking layer covering at least a portion of a trench formed in the thin film structure, a charge storage layer formed on the blocking layer, a tunneling layer formed on the charge storage layer, and a channel layer covering the tunneling layer and the substrate, wherein the charge storage layer may be doped with carbon.

### Technical Effect

According to embodiments, the conformality of the charge storage layer may be increased during the manufacturing process of the semiconductor device. Therefore, characteristics such as the threshold voltage distribution of cells included in the semiconductor device, a difference between the threshold voltages of the cells, and a difference between a threshold voltage of the cell in an upper region and that of the cell in a lower region may be lowered.

### BRIEF DESCRIPTION OF THE DRAWINGS

FIG. 1 illustrates a structure of a semiconductor device.

FIGS. 2 to 4 illustrate a process of manufacturing a semiconductor device according to an embodiment.

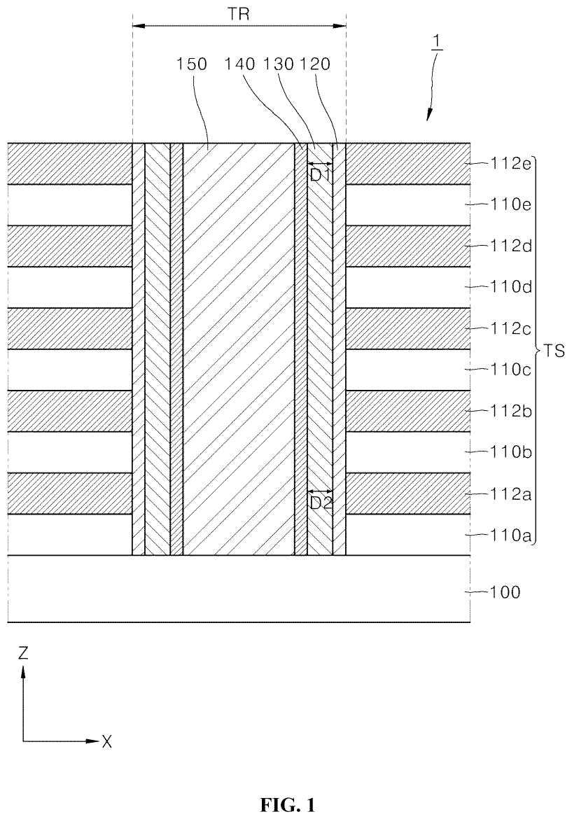

### DETAILED DESCRIPTIONS

The foregoing purposes, features, and advantages will be described in detail with reference to the accompanying drawings, and thus, those skilled in the art to which the present disclosure pertains may easily implement the embodiments of the present disclosure. In the following descriptions of the present disclosure, a detailed description of known functions and components as incorporated herein will be omitted when it may make the gist of the present disclosure rather unclear. Hereinafter, preferred embodiments of the present disclosure will be described in detail with reference to the accompanying drawings. Like reference numerals in the drawings denote the same or similar elements.

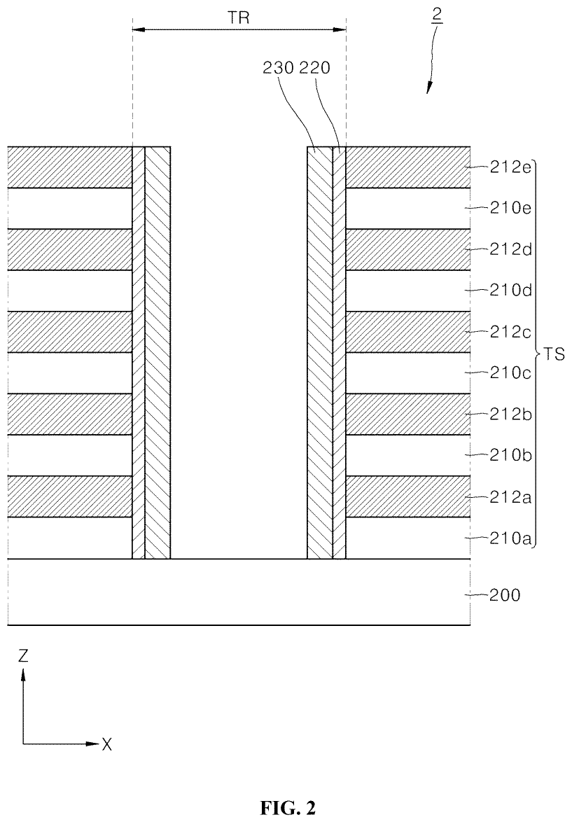

FIGS. 2 to 4 illustrate a process of manufacturing a semiconductor device according to an embodiment.

First, as shown in FIG. 2, insulating layers 210a to 210e and gate layers 212a to 212e may be alternately and repeatedly deposited on a substrate 200 to form a thin film structure TS.

In an embodiment, the substrate 200 may be a silicon substrate, a germanium substrate, or a silicon-germanium substrate. However, a type of the substrate 200 is not limited thereto.

In an embodiment, each of the insulating layers 210a to 210e may be a silicon oxide film formed through a thermal oxidation process or a silicon oxide film formed using a deposition technique. In an embodiment, the insulating layers 210a to 210e may have the same thickness. In other embodiments, some of the insulating layers 210a to 210e may have different thicknesses.

In an embodiment, each of the gate layers 212a to 212e may include a silicon nitride film formed through a nitridation process. The gate layers 212a to 212e may be sacrificial films. That is, after formation of a channel layer 250 to be described later has been completed, and then the silicon nitride films have been removed, a metal material such as Al, Cu, or W may be deposited as the gate layers 212a to 212e.

In an embodiment, the insulating layers 210a to 210e and the gate layers 212a to 212e may be formed using a thermal CVD process, a plasma enhanced CVD process, a physical CVD process, or an atomic layer deposition (ALD) process.

Next, a trench TR may be formed so as to extend through the thin film structure TS to expose the substrate 200. In a plan view, the trench TR may be two-dimensionally formed in an upper surface of the thin film structure TS. In an embodiment, the trench TR may be formed by forming a first mask pattern (not shown) having openings that define a region in which the trench TR is to be formed on the thin film structure TS, and anisotropic ally etching the thin film structure TS using the first mask pattern as an etch mask. The first mask pattern may be made of a material having etch selectivity with respect to a material of each of the insulating layers 210a to 210e and the gate layers 212a to 212e. An upper surface of the substrate 200 may be over-etched in an etching process, so that an upper portion of the substrate 200 may be recessed.

Next, a blocking layer 220 may be formed to cover at least a portion of the trench TR and expose the substrate 100. The blocking layer 220 may include a high-k dielectric film (e.g. metal oxide such as aluminum oxide or hafnium oxide) having a higher dielectric constant than that of a tunnel dielectric film.

Next, a charge storage layer 230 may be formed on the blocking layer 220. The charge storage layer 230 may include a dielectric material having traps capable of storing therein charges, for example, a nitride such as SiN and/or a metal oxide.

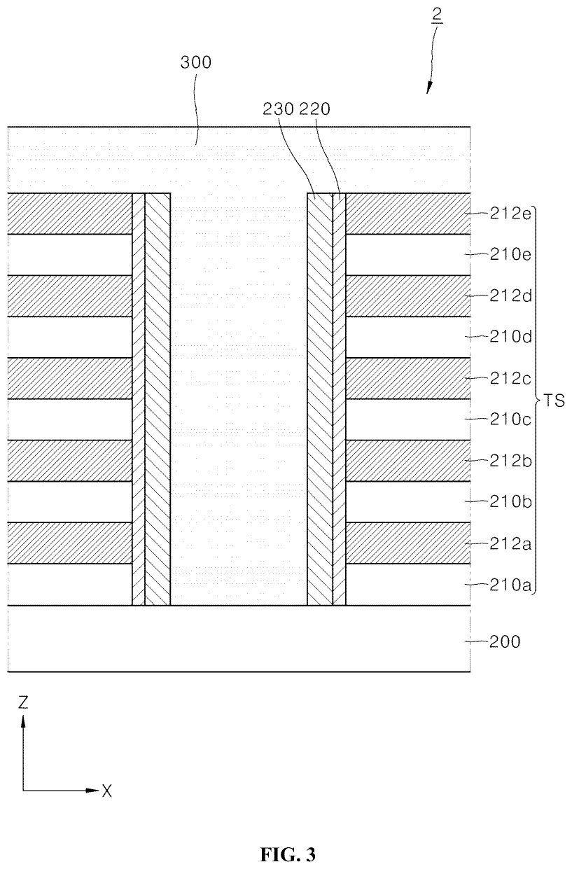

Next, as shown in FIG. 3, the charge storage layer 230 may be doped with carbon. In an embodiment, a carbon compound 300 may be supplied into a chamber in which the semiconductor device 2 in which the charge storage layer 230 has been formed is placed. In one embodiment, the carbon compound 300 supplied into the chamber may include at least one of CH₄, C₂H₄, C₂H₆, C₃H₇, C₃H₈, iC₄H₁₀, nC₄H₁₀, nC₅H₁₂, C₆H₆, C₆H₁₂, C₇H₈, C₈H₁₈, C₁₀H₂₂, or C₁₂H₂₆.

In an embodiment, an atmosphere gas may be provided into the chamber in which the semiconductor device 2 is placed. The atmosphere gas provided into the chamber may be any one or more gases of H₂, D₂, and N₂.

When the carbon compound 300 has been supplied into the chamber, heat treatment may be performed on the semiconductor device 2 in a state in which a pressure in the chamber has been set to a predetermined process pressure. In an embodiment, the process pressure may be determined as a value in a range of 1 atm to 100 atm. Further, when the heat treatment is performed, a temperature in the chamber, that is, a process temperature may be determined as a value in a range of 400° C. to 600° C.

When the carbon doping into the charge storage layer 230 has been completed by the above-described process, the semiconductor device 2 may be unloaded from the chamber to an outside. Accordingly, the carbon compound 300 as shown in FIG. 3 may be removed.

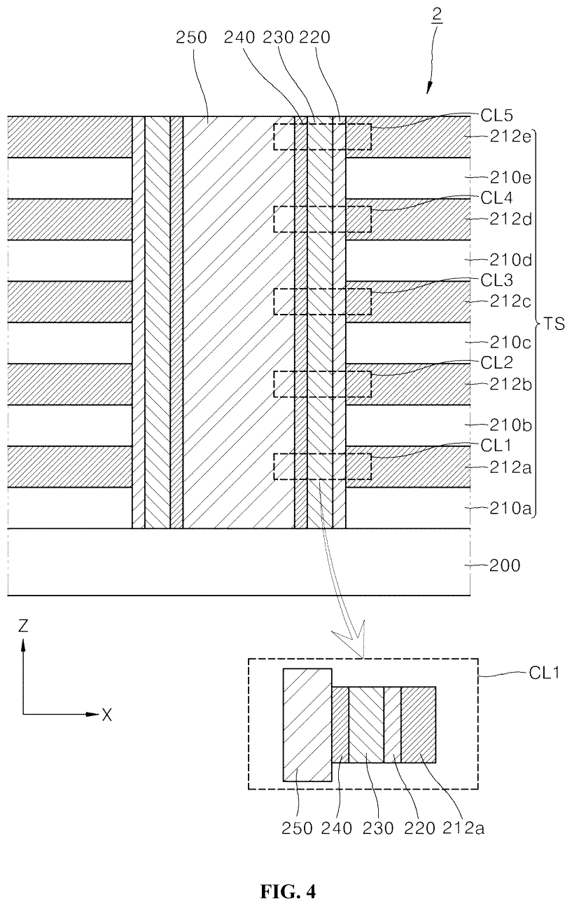

In a state in which the carbon compound 300 has been removed, as shown in FIG. 4, a tunneling layer 240 may be formed on the charge storage layer 230. The tunneling layer 240 may include an oxide and/or an oxynitride.

Next, a channel layer 250 may be formed between the tunneling layers 240. The channel layer 250 may be formed to cover a portion of the substrate 200 exposed under the trench TR. In an embodiment, the channel layer 250 may include an oxide such as polysilicon.

FIG. 4 illustrates the semiconductor device 2 according to an embodiment as produced by the above-described process. In the embodiment shown in FIG. 4, the semiconductor device 2 includes cells CL 1 to CL 5 that are stacked in five layers. However, the number of the stacked cells of the semiconductor device 2 may vary depending on an embodiment.

Each of the cells CL 1 to CL 5 included in the semiconductor device 2 has a stack structure including each of the gate layers 212a to 212e and semiconductor patterns 220, 230, 240, and 250. For example, as illustrated in FIG. 4, the first cell CL 1 may include the gate layer 212a, the blocking layer 220, the charge storage layer 230, the tunneling layer 240, and the channel layer 250 that are sequentially arranged in a horizontal direction. Each of the second to fifth cells CL 2 to CL 5 may also have the same arrangement structure as that of the first cell CL 1. In this regard, carbon may be contained into the charge storage layer 230 in the above-described carbon doping process.

According to the above-described embodiment, after the charge storage layer 230 has been formed, the carbon doping process is performed on the charge storage layer 230. When the charge storage layer 230 has been doped with the carbon, the charge storage layer 230 may have the increased conformality, thereby improving electrical characteristics of the semiconductor device 2.

First, a distribution of the threshold voltages of the cells included in the semiconductor device 2 may be improved. Table 1 shows a result of measuring threshold voltages of the cells included in each of the semiconductor devices 2 manufactured under varying process pressure when the carbon doping process into the charge storage layer 230 is performed according to the above-described embodiment. In Table 1, “undoped” refers to threshold voltage data of cells included in a semiconductor device in which the carbon doping process is not performed on the charge storage layer 230.

TABLE 1

| Process | Cell threshold voltage | | |
|---|---|---|---|
| pressure | Minimum | Maximum | Distribution |
| Undoped | 1 | 2.3 | 1.3 |
| 1 | 1.3 | 2.2 | 0.9 |
| 2 | 1.35 | 2.12 | 0.77 |
| 3 | 1.36 | 2.09 | 0.73 |
| 5 | 1.46 | 2.05 | 0.59 |
| 10 | 1.53 | 2.01 | 0.48 |
| 15 | 1.57 | 1.98 | 0.41 |
| 20 | 1.62 | 1.92 | 0.3 |
| 30 | 1.62 | 1.9 | 0.28 |

As shown in Table 1, based on a result of measuring the threshold voltages of cells included in the semiconductor device in which no carbon is contained in the charge storage layer 230, a minimum value of the cell threshold voltage is 1, a maximum value thereof is 2.3, and a distribution thereof is 1.3. On the other hand, according to the above-described embodiment, the distribution of the threshold voltages of the cells included in the semiconductor device in which the carbon doping process has been performed on the charge storage layer 230 is smaller than 1.3. Accordingly, the charge storage layer 230 has a high cell uniformity of the semiconductor device in which the carbon is contained in the charge storage layer 230, as compared with the semiconductor device in which no carbon is contained therein.

As shown in Table 1, as the process pressure when the carbon doping process is performed on the charge storage layer 230 increases, the distribution of the threshold voltages of the cells included in the semiconductor device decreases and thus the cell uniformity increases.

Further, when the carbon doping process has been performed on the charge storage layer 230 as in the above-described embodiment, the conformality of the charge storage layer 230 is higher than that when the carbon doping process is not performed on the charge storage layer 230. In other words, when the carbon doping process has been performed on the charge storage layer 230, the thickness of the charge storage layer 230 measured in the z-axis direction is uniform. Accordingly, the difference between threshold voltages of cells included in the semiconductor device 2 inn which the carbon is contained in the charge storage layer 230 is reduced, and thus the cell uniformity may be improved.

In addition, when the conformality of the charge storage layer 230 is increased due to the carbon doping process on the charge storage layer 230, the difference between the threshold voltage of the cell (e.g. the fifth cell CL 5 or the fourth cell CL 4) disposed in the upper region of the semiconductor device 2 and the threshold voltage of the cell (e.g. the first cell CL 1 or the second cell CL 2) disposed in the lower region of the semiconductor device 2 may be reduced, and thus cell uniformity may be improved.

Although the present disclosure has been described with reference to the accompanying drawings as described above, the present disclosure is not limited to the embodiments disclosed in the present disclosure and the drawings, and various modifications may be made thereto by a person skilled in the art. In addition, although an effect according to a configuration of the present disclosure is not explicitly described in describing the embodiments of the present disclosure above, a predictable effect from the configuration should also be recognized.

What is claimed is:

1. A method for manufacturing a semiconductor device, the method comprising:
forming a thin-film structure on a substrate;
forming a trench into the thin film structure;
forming a blocking layer covering at least a portion of the trench;
forming a charge storage layer on the blocking layer;
doping carbon into the charge storage layer;
forming a tunneling layer on the charge storage layer; and
forming a channel layer covering the tunneling layer and the substrate.

2. The method of claim 1, wherein the doping of the charge storage layer with the carbon includes:
when the charge storage layer has been formed, supplying a carbon compound into a chamber in which the semiconductor device has been placed; and
performing a heat treatment on the semiconductor device in a state in which a pressure in the chamber is set to a predetermined process pressure.

3. The method of claim 2, wherein the predetermined process pressure is set to a value within a range of 1 atm to 100 atm.

4. The method of claim 2, wherein an atmosphere gas is provided to the chamber,
wherein the atmosphere gas is one or more gases selected from a group consisting of H₂, D₂, and N₂.

5. The method of claim 2, wherein a process temperature of the heat treatment in the chamber is in a range of 400° C. to 600° C.

6. The method of claim 2, wherein the carbon compound includes at least one of CH₄, C₂H₄, C₂H₆, C₃H₇, C₃H₈, iC₄H₁₀, nC₄H₁₀, nC₆H₁₂, C₆H₆, C₆H₁₂, C₇H₈, C₈H₁₈, C₁₀H₂₂, or C₁₂H₂₆.

7. A semiconductor device comprising:
a substrate;
a thin film structure formed on the substrate;
a blocking layer covering at least a portion of a trench formed in the thin film structure;
a charge storage layer formed on the blocking layer,
a tunneling layer formed on the charge storage layer; and
a channel layer covering the tunneling layer and the substrate,
wherein the charge storage layer is doped with carbon.

8. The semiconductor device of claim 7, wherein when the charge storage layer has been formed, a carbon compound is supplied into a chamber in which the semiconductor device has been placed,
wherein a heat treatment is performed on the semiconductor device in a state in which a pressure in the chamber is set to a predetermined process pressure.

9. The semiconductor device of claim 8, wherein the predetermined process pressure is set to a value within a range of 1 atm to 100 atm.

10. The semiconductor device of claim 8, wherein an atmosphere gas is provided to the chamber,
wherein the atmosphere gas is one or more gases selected from a group consisting of H₂, D₂, and N₂.

11. The semiconductor device of claim 8, wherein a process temperature of the heat treatment in the chamber is in a range of 400° C. to 600° C.

12. The semiconductor device of claim 8, wherein the carbon compound includes at least one of CH₄, C₂H₄, C₂H₆, C₃H₇, C₃H₈, iC₄H₁₀, nC₄H₁₀, nC₆H₁₂, C₆H₆, C₆H₁₂, C₇H₈, C₈H₁₈, C₁₀H₂₂, or C₁₂H₂₆.
